(19) United States
(12) Patent Application Publication
(10) Pub. No.: US 2014/0013181 A1
(43) Pub. Date: Jan. 9, 2014

(54) Error Correction Coding Using Large Fields

(71) Applicant: Lisa Fredrickson, Pasadena, CA (US)

(72) Inventor: Lisa Fredrickson, Pasadena, CA (US)

(21) Appl. No.: 13/932,524

(22) Filed: Jul. 1, 2013

Related U.S. Application Data
(63) Continuation-in-part of application No. 13/541,739, filed on Jul. 4, 2012.

(51) Int. Cl. H03M 13/03

(52) U.S. Cl. CPC H03M 13/03
USPC 714/753

(57) ABSTRACT

An improved error correction system, method, and apparatus provides encoded sequences of finite field symbols, each with a plurality of associated weighted sums equal to zero, and decodes encoded sequences with a limited number of corruptions. Each of the multiplicative weights used in the weighted sums is preselected from a smaller subfield of a large finite field. Decoding proceeds by determining multiplicative weights using various operations over the smaller subfield. When a limited number of corruptions occur, improved system design ensures that the probability of decoding failure is small. The method and apparatus extend to determine one or more decoding solutions of an underdetermined set of equations, including detection of ambiguous solutions.

### CROSS-REFERENCE TO RELATED APPLICATIONS

This nonprovisional utility patent application claims the benefit of U.S. application Ser. No. 13/541,739, Construction Methods for Finite Fields with Split-Optimal Multipliers, with filing date Jul. 4, 2012. The prior filed co-pending nonprovisional application provides implementations of multipliers, inverters, and adders for large finite fields, constructed as a sequence of extension fields of smaller subfields, which are utilized in the present application.

### BACKGROUND OF THE INVENTION

A. Field of the Invention

The invention relates generally to error correction coding of data for digital communications using operations over finite fields, and particularly to a method, apparatus, and system for reliably extending error detection and correction of communicated data using large finite fields. The USPTO class 714 provides for process or apparatus for detecting and correcting errors in electrical pulse or pulse coded data, and also provides for process or apparatus for detecting and recovering from faults in electrical computers and digital data processing systems, as well as logic level based systems.

B. Related Prior Art

An (n, k) error correction code typically appends r redundant symbols to k user data symbols to provide a sequence of n symbols, the r redundant symbols determined by an encoding operation. The ratio k/n is known as the code rate, and the entire sequence of n symbols is known as a codeword. A common type of error correction code is known as a Reed Solomon code. Polynomial Codes over Certain Finite Fields, Irving S. Reed and Gustave Solomon, Journal of the Society for Industrial and Applied Mathematics (SIAM) 8 (2): pp. 300-304 (1960). Reed Solomon coding associates a sequence of n codeword symbols with coefficients of a codeword polynomial, and an encoder provides a codeword polynomial that is a multiple of a code generating polynomial. The number of bits per symbol, m, is typically in the range from 8 to 16. Reed Solomon coding operations with m-bit symbols use the addition, multiplication, and division of a finite field with 2^{m} elements, a finite field known as GF(2^{m}).

When the codeword sequence of symbols is transmitted (or stored), one or more symbols received (or recovered from storage) may be corrupted. A first form of corruption known as a symbol erasure occurs when a receiver indicates that a particular symbol in the sequence of received symbols may have an erroneous value. To correct a symbol erasure, a decoder must determine the correct symbol value at the indicated symbol location. A second form of corruption known as a symbol error occurs when a receiver estimates an erroneous value for a particular symbol without indicating an erasure. To correct the symbol error, a decoder must find the location of the erroneous symbol in the sequence of received symbols and determine the correct value of the erroneous symbol.

Error correction codes may also be cross-interleaved to improve correction capability, particularly with bursty errors. U.S. Pat. No. 4,413,340, Error correctable data transmission method, K. Odaka, Y. Sako, I. Iwamoto, T. Doi, and L. B. Vries, (1980). In a Compact Disk (CD) data storage standard, each symbol is contained in two cross-interleaved Reed Solomon codewords. Reed-Solomon Code and the Compact Disc, K. A. S. Immink, in Reed-Solomon Codes and Their Applications, S. B. Wicker and V. K Bhargava, Editors, IEEE (1994). In the standard, a first interleaved codeword is a (32, 28) code, which may be partially decoded in a prior art decoder in a first step of a two-step decoding algorithm. In the first step, a typical CD decoder processes a first interleaved (32, 28) code to correct any single error or indicate error detection to a second step decoder. The second step of a prior art two-step decoder uses the error detection indications and four redundant symbols in a second interleaved codeword to reliably correct s symbol errors and t symbol erasures provided that s+2t≦4.

A known property of Reed Solomon codes is that two different codewords with r symbols of redundancy differ in at least (r+1) symbols. If a limited number or erasures and errors occur in a received sequence of n symbols corresponding to a transmitted codeword, a decoder is able to resolve the corruptions and correctly estimate the transmitted codeword. For example, if there are s symbol erasures and t symbol errors in a Reed Solomon codeword, a prior art decoder can determine the correct codeword if s+2t≦r. When s+2t>r, a prior art decoder typically fails to decode the codeword properly. Two kinds of decoder failure are of primary concern.

An uncorrectable error is a first kind of decoder failure where a decoder signals that something occurred in decoding indicating that the correct codeword cannot be determined with certainty. In this case, a decoder typically provides an uncorrectable indicator to accompany the estimated codeword in further processing. In cross-interleaved Reed-Solomon codes, for example, a first step decoder operating on a first interleaved codeword may provide an uncorrectable indicator which becomes an erasure locator for a second step decoder operating on a second interleaved codeword.

Misdecoding is a second kind of decoder failure where one or more decoded symbols in the codeword are incorrect but the decoder does not detect and/or indicate correction uncertainty. Typically, decoder systems are required to be highly reliable, in that the probability of misdecoding is required to be very small. A higher probability of uncorrectable error is typically allowed, in part because the codeword data may be recoverable through a retransmission or storage recovery routine, if only it is known to be in error.

For example, a prior art error correction code introduced in the IBM 3370 magnetic disk drive used a Reed Solomon error correction code with three redundant eight-bit symbols per codeword, each codeword containing approximately 170 symbols of user data, and using three interleaved codewords to provide error correction coding for each 512-byte block of data. The prior art decoder could correct any codeword with a single symbol error, and detect that any codeword with two symbol errors is uncorrectable. Practical Error Correction Design for Engineers, Revised Second Edition, Neal Glover and Trent Dudley, Cirrus Logic, Bloomfield, Colo. (1991), ISBN 0-927239-00-0, pp. 274-275. A prior art decoder operating on a corrupted codeword with three or more symbol errors either indicates uncorrectable or misdecodes, depending on the error pattern.

An efficient method of decoding Reed-Solomon codewords with errors is known as the Berlekamp-Massey Algorithm (BMA). Berlekamp, E. R., Algebraic Coding Theory, Revised 1984 Ed., Aegean Park Press, Laguna Hills, Calif. (1984) ISBN 0-89412-063-8, pp. 176-189. Massey, J. L., Shift Register Synthesis and BCH Decoding in IEEE Trans Info. Theory. IT-15 (1969), pp. 122-127. In a typical structure for a BMA decoder, a first step (or unit) determines a plurality of weighted sums from an estimated codeword, the weighted sums known as syndromes. A nonzero syndrome indicates a codeword with errors. A second step (or unit) determines a polynomial known as an error locater polynomial. A third step searches to find one or more roots of the locater polynomial. At each found root of the locater polynomial, the decoder determines a correct value for an erroneous symbol at a location in the codeword sequence corresponding to the found root. When the locater polynomial is of degree two, the search to find the roots of the locater polynomial may be replaced by a direct solution using an algebraic transformation and log and antilog tables for a finite field. Practical Error Correction Design for Engineers, Revised Second Edition, Neal Glover and Trent Dudley, Cirrus Logic, Bloomfield, Colo. (1991), ISBN 0-927239-00-0, pp. 152-156. In an extension of the Berlekamp-Massey Algorithm, the second step of the BMA method described above is modified to provide an error-and-erasure locater polynomial. The modified Berlekamp-Massey Algorithm (MBMA) can be used to correct both errors and erasures in a corrupted codeword. Blahut, R. E., Theory and Practice of Error Control Codes, Addison-Wesley ISBN 0-201-10102-5 (1983), pp. 256-260.

A known limitation of Reed Solomon coding over a finite field GF(2^{m}) is that the total number of bits per codeword, B, is approximately limited to B<m2^{m}. Because the number of bits per symbol is typically limited to the range from eight to sixteen, the growth of coding symbol sizes (and block transfer sizes) has not kept pace with the growth of typical bus sizes (and transfers) of modern computer systems, now typically at 32 or 64 bits per bus symbol with storage block and memory page sizes starting at 32K bits. Larger bus and block sizes are desired to support higher system throughput and larger data records. Although traditional Reed Solomon coding is possible in larger finite fields, the complexity of the required components tends to grow exponentially, whereas the throughput grows linearly.

Improved error correction codes and decoding methods are desired to overcome limitations of the prior art. In particular, improved coding methods are desired for codewords with larger code symbols from larger finite fields, preferably retaining the simplicity of coding operations from smaller subfields. In addition, improved coding methods are desired which provide higher throughput in coding operations, better protection against misdecoding, and more correction power for a given code rate.

In U.S. application Ser. No. 13/541,739, Construction Methods for Finite Fields with Split-Optimal Multipliers (2012), the applicant specified improved construction methods for finite fields, and, in particular, for large finite fields with a large number of bits per symbol. Methods of coding for large finite fields are desired which achieve the benefits of higher system throughput using larger symbols, but without the exponential growth in implementation complexity.

### BRIEF SUMMARY OF THE INVENTION

An improved error correction system encodes sequences of finite field symbols, each with a plurality of associated weighted sums equal to zero, and decodes encoded sequences with a limited number of corruptions. Each of the multiplicative weights used in the weighted sums is preselected from a smaller subfield of a large finite field representing the symbols. A method and apparatus for decoding encoded sequences with one or more symbol corruptions determines the multiplicative weights associated with the locations of the symbol errors using various operations over the smaller subfield. Code parameters are limited and decoding includes a plurality of checks to ensure that when a limited number of corruptions occur, the probability of decoding failure is small. The method and apparatus extend to determine one or more decoding solutions of an underdetermined set of equations, including detection of ambiguous solutions.

### BRIEF DESCRIPTION OF THE SEVERAL VIEWS OF THE DRAWING

FIG. 1 is a schematic of a preferred hardware encoder circuit for two redundant symbols, assuming that a particular set of preferred subfield weights is used.

FIG. 2 is a schematic of a simplified multiplier, multiplying a finite field symbol by a weight from a subfield of the finite field, to provide a weighted symbol output.

FIG. 3 is a schematic of a simplified divider to determine the weight of an error location.

FIG. 4 is a schematic of an example circuit to determine intermediate variables representing a finite field sum and two weighted sums for a sequence of symbols.

FIG. 5 is a schematic of an auxiliary encoder circuit to convert intermediate values to redundant symbols with a preferred set of location weights.

FIG. 6 is a schematic of an example decoder circuit useful in determining error values for three arbitrary locations, x, y, and z.

FIG. 7 is a schematic of an example sequential circuit to provide three error values.

FIG. 8 is a flowchart of steps of an example method to decode one or more erroneous symbols with unmarked error locations.

FIG. 9 is a schematic of an example parallel circuit to determine two error values.

### DETAILED DESCRIPTION OF THE INVENTION

### A. A Single Error Correcting Code Using Larger Fields

A hypothetical prior code with (n, k)=(175, 172) for single error correction with 8-bit symbols is akin to the Reed Solomon code used in the IBM 3370 (1979). Coding is performed there using the 8-bit finite field, GF(256). The hypothetical prior art code is used as a basis for comparison with an example code using only two redundant symbols per codeword, the (k+2, k) code specified here.

If a code with only two redundant symbols is used for single error correction, there is a concern that the performance tradeoff between error detection capability and misdecoding probability may be compromised, particularly when two errors occur. Accordingly, a (k+2, k) code for reliably correcting a single error without compromising misdecoding performance is described.

### A.1. Code Definition

Let {d₀, d₁, . . . , dₖ₋₁} be a sequence of data symbols to be encoded, and let {c₀, c₁, . . . , cₙ₋₁} be the corresponding codeword at the output of the encoder. In error correction coding, systematic codes are generally preferred, although it is not necessary to limit the codes in this manner.

In a systematic code, the data symbols appear as the beginning sequence of the codeword, with cᵢ=dᵢ for 0≦i<k. Two redundant symbols are appended to the sequence to provide that any codeword satisfies the two equations

$$S = {\sum }_{j = 0}^{n - 1} {c}_{j} = 0$$

$$and$$

$$W = {\sum }_{j = 0}^{n - 1} {w}_{j} {c}_{j} = 0$$

where {w₀, w₁, . . . , wₙ₋₁} is a set of pre-determined symbol weights. Here it is required that each symbol weight is nonzero and unique in that wᵢ≈wⱼ when i≈j. The summation symbol refers to finite field addition, whereas the weighted products are determined using finite field multiplication.

The selection of weights is flexible. For example, the user may prefer to use weights of the form

{wⱼ=α^{n-1-j}}ⱼ₌₀ⁿ⁻¹,

using a so-called primitive element α of the finite field, with the redundant symbols corresponding to those used in a standard Reed Solomon code. For reasons explained further below, a set of weights spanning a linear range, such as those of the form

{wⱼ=n−j}ⱼ₌₀ⁿ⁻¹,

that is, the set

{w₀,w₁, . . . ,wₙ₋₁}={n,n−1, . . . ,1},

is preferred.

### A.2. Encoding

The encoder assigns the first k symbols of the codeword systematically as described above. In one method of encoding, intermediate variables representing an initial finite field sum S and an initial weighted W sum are determined.

$$S = {\sum }_{j = 0}^{k - 1} {c}_{j}$$

$$W = {\sum }_{j = 0}^{k - 1} {w}_{j} {c}_{j}$$

The redundant symbols are then provided as weighted sums of S and W.

cₖ=(wₖ₊₁S+W)/(wₖ+wₖ₊₁), and

cₖ₊₁=(wₖS+W)/(wₖ+wₖ₊₁)=S+cₖ.

The redundant symbols are appended to the data sequence to complete encoding.

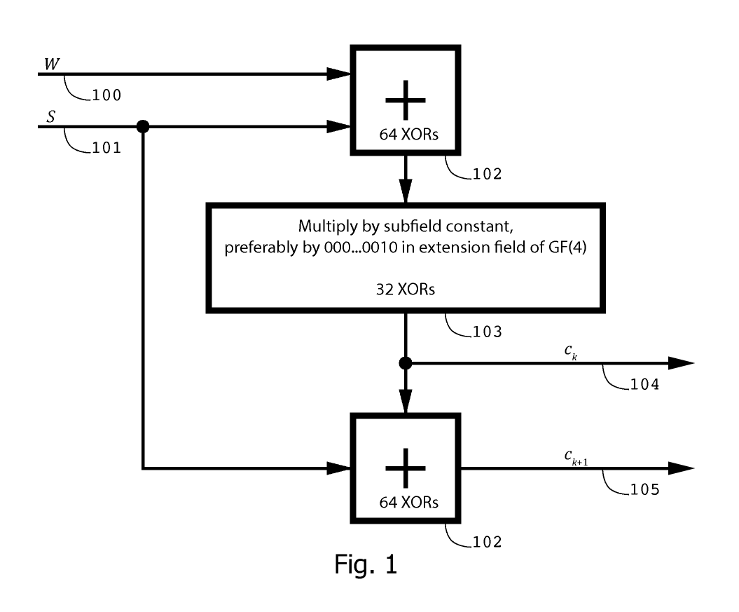

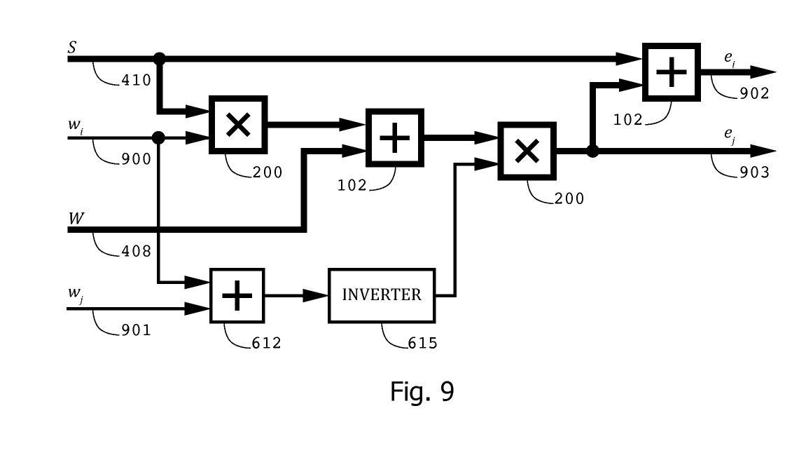

FIG. 1 is a schematic of a preferred hardware encoder circuit for two redundant symbols, assuming that a particular fixed set of preferred subfield weights is used at redundancy locations. A circuit for determining two symbols as above at arbitrary locations with varying subfield weights is shown in FIG. 9. The circuits assume that the intermediate variables W and S are members of a large finite field used to represent code symbols, whereas symbol weights are members of a smaller subfield of the large finite field. In examples shown below, the large finite field uses example 64-bit symbols, but the example weighting factors are from a 2-bit subfield GF(4), a 4-bit subfield GF(16), an 8-bit subfield GF(256), or a 16-bit subfield GF(65536). The intermediate variables W and S are determined externally and supplied on inputs 100 and 101 of FIG. 1, respectively. An example circuit for determining W and S specified further below. The circuit of FIG. 1 outputs the two redundant symbols, cₖ 104 and cₖ₊₁ 105.

A preferred set of weights has wₖ₊₁=1, simplifying the determination of cₖ. The sum W+S is determined in a first large finite field adder 102. With wₖ=2 and using a 64-bit extension field constructed from the 2-bit subfield GF(4), as in examples in U.S. application Ser. No. 13/541,739, Construction Methods for Finite Fields with Split-Optimal Multipliers, the inverse of wₖ+wₖ₊₁ is also a preferred member of the subfield GF(4). Multiplication of a 64-bit sum W+S by the preferred subfield constant is provided by 32 parallel constant multipliers for subfield GF(4), each operating on two consecutive bits of the large finite field sum. The 32 parallel constant multipliers are preferably implemented with a total of 32 exclusive-OR gates (XORs) and a rearrangement of bits in constant multiplier 103, providing the output cₖ 104. The output of 103 is also added to S 101 in a second 64-bit finite field adder 102, providing the output cₖ₊₁ 105.

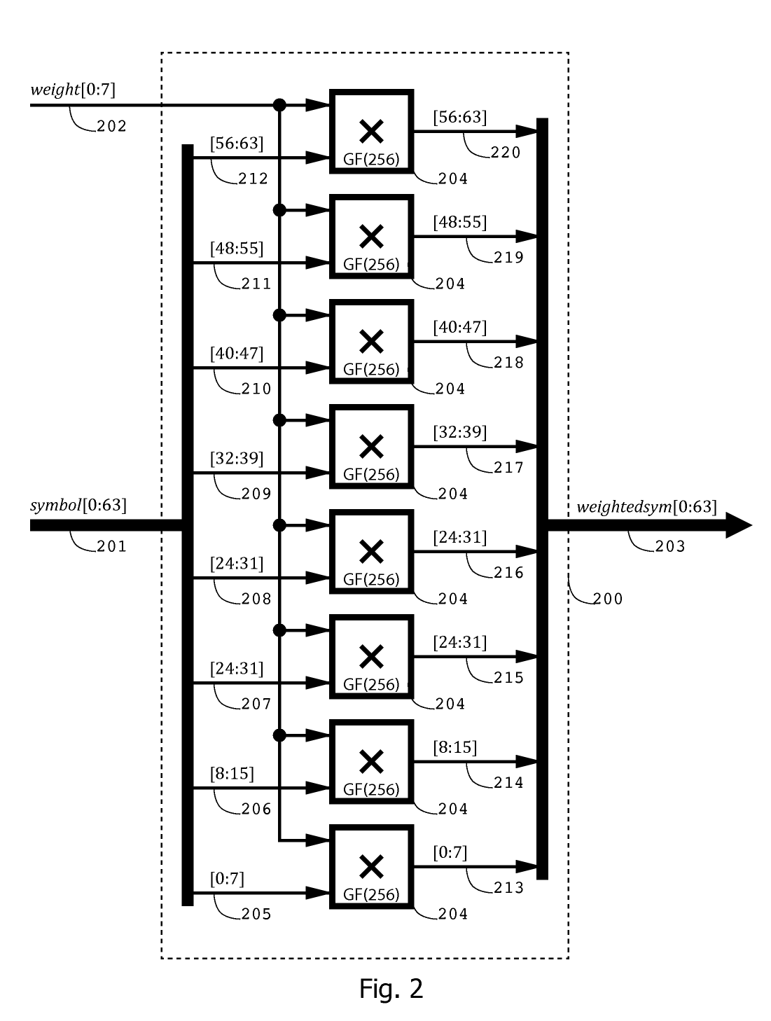

When the number of symbol locations is relatively small compared to the size of the finite field, members of a relatively small subfield are preferably selected as the location weights. FIG. 2 is a schematic of a simplified multiplier 200, multiplying a finite field symbol 201 by a weight 202 from a subfield of the finite field, to provide a weighted symbol output 203. In this example, the subfield uses 8-bit weights and the large finite field uses 64-bit symbols. This example implementation provides a set of up to 255 unique nonzero symbol weights from GF(256), the weights corresponding to at most 255 locations of 64-bit symbols in a codeword.

When the weights are contained within a subfield, the large field multiplication for weighting symbols simplifies to a plurality of parallel subfield multiplications. In this example, eight parallel 8-bit multipliers for GF(256) provide the 64-bit weighting multiplication. In FIG. 2, the 64 bits of an input symbol bus 201 are denoted with a range of bit indices, [0:63]. A first byte bus 205 of the input symbol bus 201 contains eight of said bits with a range of bit indices [0:7]. Similarly, byte busses 206-212 each contain an additional eight bits of the input symbol bus 205, with a range of bit indices denoted [8:15] in 206 through [56:63] in 212, respectively. A first subfield multiplier 204 multiplies byte bus 205 by input weight 202 to produce output byte bus 213 using the multiplication of GF(256). Similarly, seven more subfield multipliers 204 provide the remaining seven output byte busses 214-220. The output byte busses 213-220 are combined in parallel to produce the 64-bit weighted symbol output 203.

Alternatively, if larger (or smaller) codewords are desired, a different subfield such as a larger 16-bit (or a smaller 4-bit) subfield may be used for the symbol weights, providing that a codeword has, at most, 65535 (or 15) 64-bit symbols. In the 16-bit case, the 64-bit by 16-bit multiplication for weighting symbols is provided by a similar implementation (not shown), but with four parallel 16-bit GF(65536) multipliers instead of the eight parallel GF(256) multipliers. As a practical matter, a smaller subfield such as GF(256) will provide a sufficient codeword size with less complexity for many purposes.

### A.3. Decoding Single Errors

Suppose that a receiver provides an estimate of the transmitted codeword, with the estimated symbol sequence denoted {h₀, h₁, . . . , hₙ₋₁}. If a single error occurs, then

hᵢ≈cᵢ for some 0≦i<n, and

hⱼ=cᵢ for all j≈i.

Define the error value at location i, eᵢ, as the finite field sum, eᵢ=cᵢ+hᵢ.

In one method of decoding, intermediate variables representing a finite field sum and a weighted sum of the estimated sequence are determined as follows.

$$S = {\sum }_{j = 0}^{n - 1} {c}_{j}$$

$$W = {\sum }_{j = 0}^{n - 1} {w}_{j} {c}_{j}$$

When there is a single error, it follows that S=eᵢ and W=wᵢeᵢ. If both S and W are nonzero, the decoder determines the weight associated with the error location

wᵢ=W/S

and the location of the error, i, from the associated weight. For example, if the pre-selected weights are of the form wᵢ=n−i, then the decoder determines the location using i=n−wᵢ, the subtraction performed using binary arithmetic. The decoder also checks if the determined location is within the proper range for a codeword location, i.e., if 0≦i<n. If so, the decoder assumes successful decoding, correcting location i by adding in the error value using finite field addition, cᵢ=eᵢ+hᵢ.

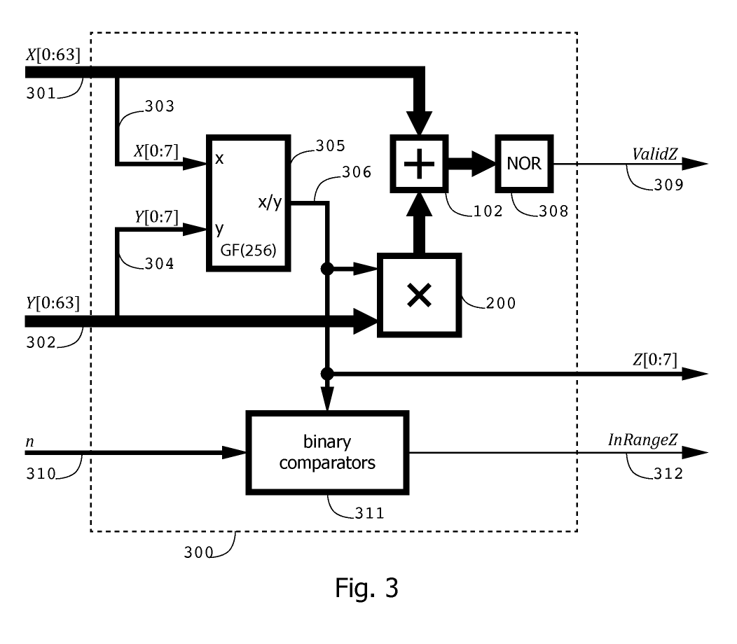

In a preferred embodiment, all of the pre-selected location weights are contained within a smaller subfield of the symbol field. FIG. 3 is a schematic of a simplified divider 300 to determine the weight of an error location. As before, the example implementation of FIG. 3 represents an example code with 64-bit symbols and an 8-bit location weighting subfield. In FIG. 3, a first large field symbol denoted X[0:63] 301 is divided by a second large field symbol denoted Y[0:63] 302.

Suppose that X, Y, and Z are symbols in a finite field. If Z=X/Y, then X=YZ. Assuming that Z represents a valid location weight in a subfield, such as GF(256), Z can be determined by dividing a bus 303 representing a subfield component of X, X[0:7], by a bus 304 representing a subfield component of Y, Y[0:7], to produce a subfield quotient Z[0:7] 306. The subfield quotient Z[0:7] 306 is multiplied by the field symbol Y[0:63] 302 in a simplified symbol weighting multiplier 200 as shown in FIG. 2. The output of weighting multiplier 200 is added to symbol X[0:63] 301 in finite field adder 102. If the assumption that the quotient represents a member of the subfield is valid, the output of finite field adder 102 is zero. The output of a 64-input NOR gate 308 indicates the assumption is valid on output indicator ValidZ 309. If the quotient is a valid member of the preferred subfield, the location is checked further against the range of allowed codeword locations using binary comparators 311 with an input n 310 representing the number of codeword symbols. If the location is a viable codeword location, an output InRangeZ 312 is asserted. If ValidZ 309 and InRangeZ 312 are asserted, decoder control logic (not shown) assumes successful decoding and the error value is corrected.

When the decoder control logic supplies intermediate value W to input X[0:63] 301 and intermediate value S to input Y[0:63] 302, the output Z[0:7] 306 represents the weight associated with a location i of the single error. Determining the location i from the associated weight, the decoder corrects location i by adding in the error value using finite field addition, cᵢ=eᵢ+hᵢ (not shown).

### A.3. Detecting More Errors

Suppose instead that two symbol errors are present in the estimated codeword. If two or more errors occur, a single error correcting decoder provides an error detection indication if either S or W is zero, or the determined location is out of range. The probability that a random two-error pattern results in S being zero is

$$\frac{1}{Q - 1} ,$$

where Q is the number of elements in the finite field. W is zero with the same probability. The probability that a random two-error pattern results in a viable single error location leading to misdecoding is approximated by

n/(Q−1).

Using a typical Reed Solomon codeword size and finite field size for error correction purposes, such as n=175 and Q=256, this is an unacceptably high misdecoding rate.

To provide adequate protection against misdecoding, a large finite field with n<<Q is utilized for coding purposes. The finite field may be constructed using the teachings of U.S. patent application Ser. No. 13/541,739, Construction Methods for Finite Fields with Split-Optimal Multipliers. For example, if a single-error correcting code with 175 symbols uses a 64-bit symbol field, the conditional probability of misdecoding given two random errors is less than 1E-17 (that is, 10⁻¹⁷).

### A.4. Brief Summary of Code Features

This simple code provides the same single error correction capability as a prior art implementation with three redundant symbols, but with greater efficiency due to its higher k/(k+2) code rate and with enhanced misdecoding performance. In addition, the coding method provides several implementation advantages.

A first advantage of the codes specified here is that, because n is small compared to Q, a set of weights can be pre-selected with each weight belonging to a small subfield of GF(Q). The finite field multiplications and divisions used in coding operations can be performed using simplified functions multiplying (or dividing) a symbol from GF(Q) by a quantity belonging to a small subfield of GF(Q). More simplified functions are explained further below. Construction of large fields from suitable subfields is described in U.S. application Ser. No. 13/541,739, Construction Methods for Finite Fields with Split-Optimal Multipliers.

A second advantage of the codes disclosed here is that the set of pre-selected weights can facilitate checking of potential error locations. In this example, a preferred set of weights associated with valid error locations spans a linear range, and a single error solution is considered valid if 0<wᵢ≦n. This check can be provided by simple binary comparison.

A third advantage of the codes disclosed here is that the set of pre-selected weights can facilitate generation of redundant symbols. As described below, a common multiplier-accumulator circuit can be used to generate intermediate variables useful for both encoding and decoding purposes. As shown in FIG. 1, the example preferred weights provide a simple auxiliary determination to complete the encoding process.

Common implementation features of the simple (k+2, k) single error correcting code are described further in conjunction with a double-error correcting (k+3, k) double error correcting code specified in the next section.

### B. A Double Error Correcting Code Using Larger Fields

### B.1. Code Definition

Let {d₀, d₁, . . . , dₖ₋₁} be a sequence of data symbols to be encoded, and let {c₀, c₁, . . . , cₙ₋₁} be the corresponding codeword at the output of the encoder. In error correction coding, systematic codes are generally preferred, although it is not necessary to limit the codes in this manner. In this section, a generalized method of encoding for both systematic and non-systematic placement of data symbols is specified. Any codeword has a sum and two weighted sums required to satisfy three equations:

$$S = {\sum }_{j = 0}^{n - 1} {c}_{j}$$

$$W = {\sum }_{j = 0}^{n - 1} {w}_{j} {c}_{j}$$

$$A = {\sum }_{j = 0}^{n - 1} {a}_{j} {c}_{j}$$

As above, the set {w₀, w₁, . . . , wₙ₋₁} is a pre-determined set of distinct nonzero symbol weights. The associated weight set {a₀, a₁, . . . , aₙ₋₁} is also a pre-determined set of distinct nonzero symbol weights.

For any two locations, {x, y} with 0≦x≈y<n, with weights and associated weights {wₓ, w_{y}, aₓ, a_{y}}, define

Δ(x,y)=wₓa_{y}+w_{y}aₓ,

determined using the multiplication and addition of the finite field. The code requires that the weights of distinct symbol locations, {x, y}, satisfy Δ(x, y)≈0. Similarly, any three distinct locations, {x, y, z}, satisfy

Δ=Δ(x,y)+Δ(x,z)+Δ(y,z)≈0.

Otherwise, assignment of the associated weight set is flexible.

It is preferred that an associated weight aᵢ can be easily determined from the corresponding weight wᵢ. A first preferred auxiliary weight set has

aᵢ=wᵢ⁻¹

for all i. In this case, a field inversion converts a known weight to the associated weight or vice versa. Preferably, the weights and associated weights belong to a smaller subfield of a large symbol field, providing that the weight conversion may be accomplished with a simplified subfield inversion. A second preferred auxiliary weight set is aᵢ=wᵢ² for all i.

### B.2. Encoding

In this alternate encoding description, the redundant symbols to be generated are treated as erasures, and determined by a form of erasure decoding. Let {h₀, h₁, . . . , hₙ₋₁} denote a preliminary assigned sequence to be modified for encoding purposes.

In this more general description, the k data symbols may be assigned to any of the k symbols within the sequence of n=k+3 symbols, {h₀, h₁, . . . , hₙ₋₁}. The redundant symbols are to be placed at three remaining locations, x, y, and z, where 0≦x<y<z<n. To generate the redundant symbols, temporarily set hₓ=h_{y}=h_{z}=0. Intermediate variables, {S, W, A}, representing a finite field sum and two weighted sums for the preliminary sequence, are determined:

$$S = {\sum }_{j = 0}^{n - 1} {h}_{j}$$

$$W = {\sum }_{j = 0}^{n - 1} {w}_{j} {h}_{j}$$

$$A = {\sum }_{j = 0}^{n - 1} {a}_{j} {h}_{j}$$

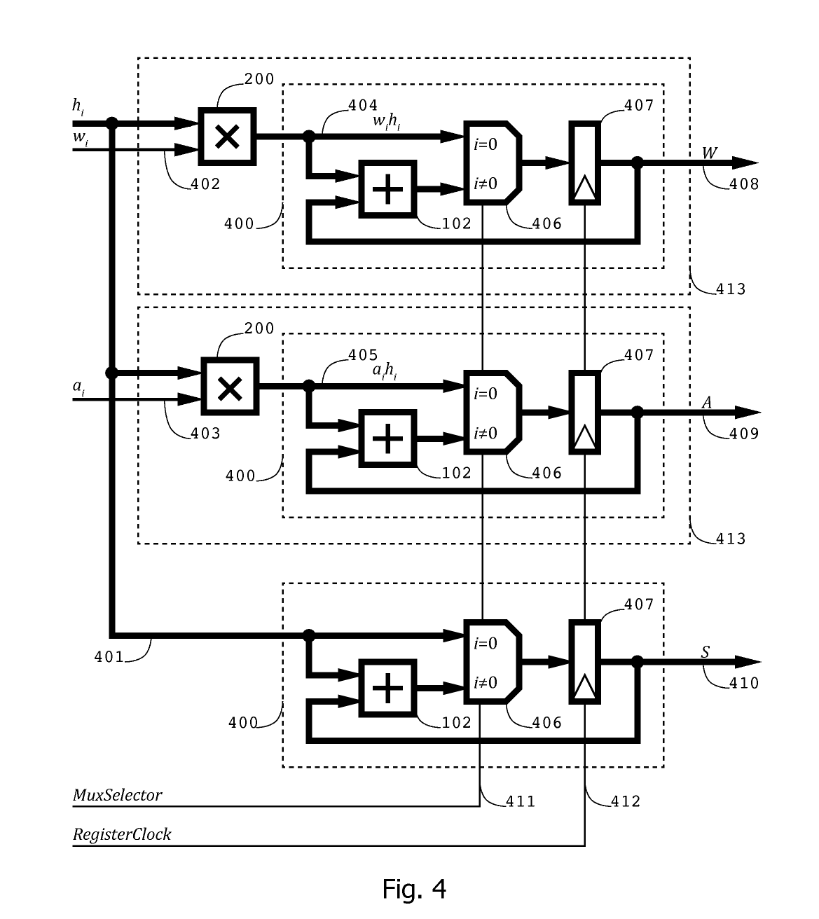

FIG. 4 is a schematic of an example circuit to determine the intermediate variables representing the finite field sum and the two weighted sums for the preliminary sequence. A particular symbol in the sequence of preliminary code symbols is provided on input hᵢ 401. At the same time, the weight and associated weight assigned to location i are provided on input wᵢ 402 and input aᵢ 403. Two weighting multipliers 200 are used to output a first weighted symbol wᵢhᵢ 404 and a second weighted symbol aᵢhᵢ 405. Note that the multipliers 200 are preferably simplified multipliers, as shown in FIG. 2, multiplying a large finite field symbol by a smaller subfield weight. Three finite field accumulators 400 produce three outputs of the circuit, a first output W 408, a second output A 409, and a third output S 410. In this example with 64-bit code symbols, each of the three finite field accumulators 400 comprises a 64-bit finite field adder 102, a 64-bit multiplexer 406 with a common MuxSelector input 411, and a 64-bit register 407 with a common RegisterClock input 412.

The implementation shown in FIG. 4 contains three parallel calculations, a first calculation using an accumulator 400, and two calculations using two parallel multiplier-accumulator (MAC) units 413, each comprising a weighing multiplier 200 and an accumulator 400. In an alternative embodiment (not shown), a single MAC unit 413 with input weight switching can be used to sequentially produce the output sums and weighted sums.

When a first preliminary symbol in a codeword is present on input hᵢ 401, multiplexers 406 under the external control of MuxSelector input 411 provide the multiplexer input labeled “i=0” to the register 407. When the remaining preliminary symbols in a codeword are present on input hᵢ 401, the external control of MuxSelector input 411 provides the multiplexer input labeled “i≈0” to the register 407. The register 407 contents are updated synchronously at times determined by input RegisterClock 412, with one update per clock cycle. When register updates are completed for all nonzero codeword symbols input on 401, the intermediate variables W 408, A 409, and S 410 are fully determined at the output of the three finite field accumulators 400.

It follows that the error in the actual code symbols at x, y, and z must satisfy the following matrix equation:

$$[ \begin{matrix}1 & 1 & 1 \\ {w}_{x} & {w}_{y} & {w}_{z} \\ {a}_{x} & {a}_{y} & {a}_{z}\end{matrix} ] [ \begin{matrix}{e}_{x} \\ {e}_{y} \\ {e}_{z}\end{matrix} ] = [ \begin{matrix}S \\ W \\ A\end{matrix} ]$$

Let Δ be the determinant of the weighting matrix,

$$Δ = \vert \begin{matrix}1 & 1 & 1 \\ {w}_{x} & {w}_{y} & {w}_{z} \\ {a}_{x} & {a}_{y} & {a}_{z}\end{matrix} \vert = Δ ( x , y ) + Δ ( x , z ) + Δ ( y , z ) .$$

If Δ ≈0, the matrix equation provides a unique set of error values,

eₓ=(SΔ(y,z)+W[a_{y}+a_{z}]+A[w_{y}+w_{z}])/Δ,

e_{y}=(SΔ(x,z)+W[aₓ+a_{z}]+A[wₓ+w_{z}])/Δ, and

e_{z}=(SΔ(x,y)+W[aₓ+a_{y}]+A[wₓ+w_{y}])/Δ.

In the encoding process, the three error values replace the temporary zeroes at locations x, y, and z within the preliminary codeword sequence. The codeword sequence is given by

cᵢ=eᵢ if {i=x,y, or z}, and cᵢ=hᵢ otherwise.

Encoding can be simplified through a judicious choice of weights. For example, a preferred set of weights is

wⱼ=n−j.

Two preferred sets of auxiliary weights are

aⱼ=wⱼ⁻¹ (denoted alternative Aux₁) or aᵢ=wⱼ² (denoted alternative Aux₂).

A preferred finite field for code symbols is an extension field of the finite field GF(4), as explained further in examples in U.S. application Ser. No. 13/541,739, Construction Methods for Finite Fields with Split-Optimal Multipliers. In this simplified case, the redundant symbols may be assigned to locations {k, k+1, k+2} with weightings {wₖ, wₖ₊₁, wₖ₊₂}={3, 2, 1} respectively, and associated weightings using either Aux₁ or Aux₂. In either case, the weighting matrix is given by

$$[ \begin{matrix}1 & 1 & 1 \\ {w}_{x} & {w}_{y} & {w}_{z} \\ {a}_{x} & {a}_{y} & {a}_{z}\end{matrix} ] = [ \begin{matrix}1 & 1 & 1 \\ 3 & 2 & 1 \\ 2 & 3 & 1\end{matrix} ] , \\ with \\ Δ ( x , y ) = Δ ( y , z ) = Δ ( x , z ) = Δ = 1.$$

The simplified redundancy determination is then

cₖ=S+2W+3A,

cₖ₊₁=S+3W+2A, and

cₖ₊₂=S+W+A.

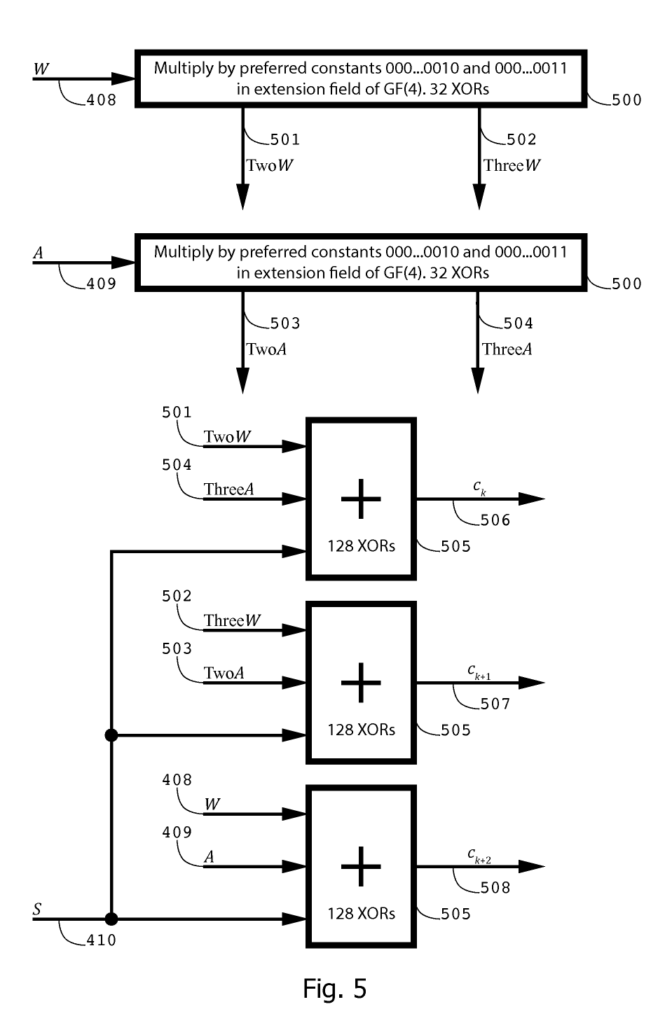

FIG. 5 is a schematic of an auxiliary encoder circuit to convert intermediate values to redundant symbols with a preferred set of location weights. The intermediate variables are determined in an external circuit and supplied to the auxiliary circuit inputs. Here, intermediate variables are assumed to be from a large extension field of GF(4), such as a finite field with 64-bit symbols.

Intermediate variable W is provided externally to signal bus 408, and is the input of a first dual constant multiplier unit 500. With 64-bit symbols, multiplication of an input by the two preferred constants can be accomplished with 32 XOR gates in dual multiplier unit 500 and two rearrangements of signal bits. A first output TwoW 501 of dual multiplier unit 500 provides finite field multiplication of the input W by the subfield constant 2. A second output ThreeW 502 provides finite field multiplication of the input W by the subfield constant 3. Similarly, intermediate variable A is input on signal bus 409, and is the input of a second dual constant multiplier unit 500. A first output TwoA 503 provides finite field multiplication of the input A by the subfield constant 2. A second output ThreeA 504 provides finite field multiplication of the input A by the subfield constant 3.

Intermediate variable S is input on signal bus 410, and is the input of three three-input finite field adder units 505. In this example, summation of three 64-bit symbols requires the equivalent of 128 XOR gates. The first adder unit 505 determines the finite field sum of signal busses 501, 504, and 410 to output the first redundant symbol cₖ 506. The second adder unit 505 provides the finite field sum of signal busses 502, 503, and 410 to output the second redundant symbol cₖ₊₁ 507. The third adder unit 505 inputs signal busses 408, 409, and 410 to output the third redundant symbol Cₖ₊₂ 508. An alternative implementation (not shown) uses a single adder unit 505 with input switching to produce the three outputs sequentially.

### B.3. Erasure Decoding

Let {h₀, h₁, . . . , hₙ₋₁} denote an estimated codeword sequence at the output of a receiver. The estimator provides one or more erasure location markers for symbols it may have incorrectly estimated. An erasure decoder attempts to determine the symbol error values at each of the marked erasure locations. An error value eₓ at location x is defined as the finite field difference between the estimated symbol hₓ and the actual codeword symbol cₓ,

eₓ=hₓ+cₓ,

where the difference is determined using finite field addition in a field of characteristic two.

A decoder first determines the intermediate variables representing a finite field sum and two weighted sums, {S, W, A} as in the previous section. If at most three of the marked erasure locations are in error, and no other errors are present, it follows that the error values at x, y, and z must satisfy the same matrix equation as in the previous section,

$$[ \begin{matrix}1 & 1 & 1 \\ {w}_{x} & {w}_{y} & {w}_{z} \\ {a}_{x} & {a}_{y} & {a}_{z}\end{matrix} ] [ \begin{matrix}{e}_{x} \\ {e}_{y} \\ {e}_{z}\end{matrix} ] = [ \begin{matrix}S \\ W \\ A\end{matrix} ] .$$

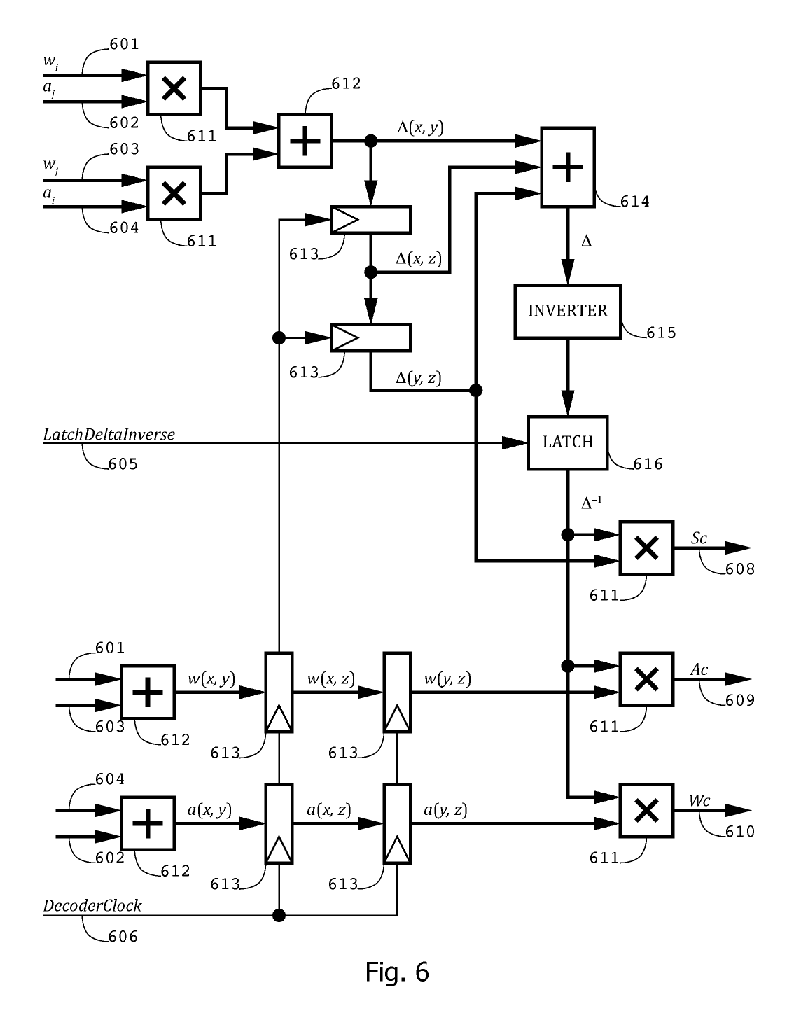

FIG. 6 is a schematic of an example decoder circuit useful in determining error values for three arbitrary locations, x, y, and z. If the pre-assigned sets of weights and associated weights are contained within a subfield of the symbol field, the various components of FIG. 6 are simplified components with subfield inputs and subfield outputs. If, for example, all weights and associated weights used in FIG. 6 are contained within the subfield GF(256), five multipliers 611 are 8-bit finite field multipliers for GF(256), three two-input adders 612 and one three-input adder 614 are 8-bit finite field adders, six registers 613 are 8-bit registers, and inverter 615 is an 8-bit GF(256) inverter.

An external controller provides a weight wᵢ 601 and an associated weight aᵢ 604 for a first marked erasure location i, and a weight wⱼ 602 and an associated weight aⱼ 603 for a second marked erasure location j. Two subfield multipliers 611 and a first subfield adder 612 provide a sub-determinant

Δ(i,j)=wᵢaⱼ+wⱼaᵢ,

as defined above. The decoder circuit in FIG. 6 has a DecoderClock input 606 that causes all registers 613 to update synchronously once per clock cycle. An external controller provides the weights and associated weights for the three marked locations at x, y, and z, in succession as required at 601-604 to produce three successive sub-determinants Δ(y, z), Δ(x, z), and Δ (x, y) at the outputs of two registers 613 and the first subfield adder 612 as shown. The three sub-determinants are input to adder 614 to provide the output

$$Δ = \vert \begin{matrix}1 & 1 & 1 \\ {w}_{x} & {w}_{y} & {w}_{z} \\ {a}_{x} & {a}_{y} & {a}_{z}\end{matrix} \vert = Δ ( x , y ) + Δ ( x , z ) + Δ ( y , z ) .$$

An inverter 615 provides the finite field multiplicative inverse of Δ, denoted Δ⁻¹. If the preferred weights and associated weights are contained within a subfield, the inverter 615 is a simplified subfield inverter. Transparent latch 616, under the control of external input LatchDeltaInverse 605, maintains Δ⁻¹ constant at the output despite changes at the output of adder 614. By defining the three subfield scalars

Sc=Δ⁻¹Δ(y,z),

Wc=Δ⁻¹(a_{y}+a_{z})=Δ⁻¹a(y,z), and

Ac=Δ⁻¹(w_{y}+w_{z})=Δ⁻¹w(y,z),

it follows that

eₓ=(SΔ(y,z)+W[a_{y}+a_{z}]+A[w_{y}+w_{z}])/Δ=ScS+WcW+AcA.

Sums of weights, such as

w(y,z)=w_{y}+w_{z},

are produced in a second adder 612 and exit a delay line with two registers 613. Sums of associated weights, such as

a(y,z)=a_{y}+a_{z},

are provided by a third adder 612 and exit a delay line with two more registers 613. The three quantities, Δ(y, z), the sum w(y, z), and the sum a(y, z), are multiplied by the multiplicative inverse of Δ in the three finite field multipliers 611, providing the outputs Sc 608, Ac 609, and Wc 610.

At the completion of the next clock cycle, the output of latch 616 remains unchanged, but the other input to the three multipliers 611 are the three quantities, Δ(x, z), the sum w(x, z), and the sum a(x, z). It follows that the updated multiplier 611 outputs Sc 608, Ac 609, and Wc 610 are appropriate to provide

e_{y}=ScS+WcW+AcA.

Similarly, at the completion of the succeeding clock cycle, the multiplier 611 outputs a new Sc 608, Ac 609, and Wc 610 that are appropriate to provide

e_{z}=ScS+WcW+AcA.

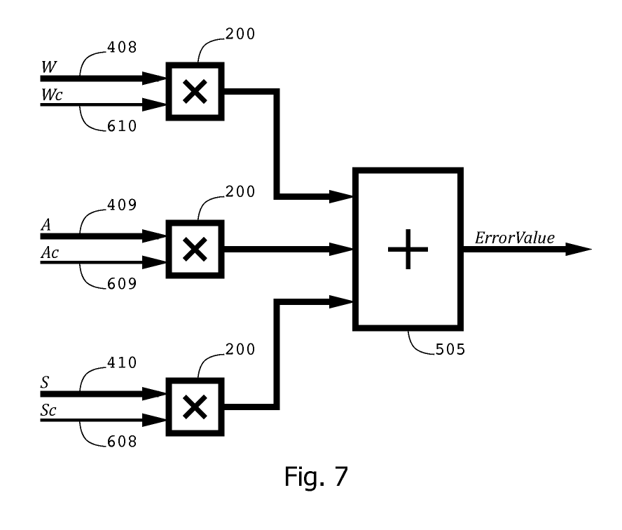

FIG. 7 is a schematic of an example sequential circuit to provide three error values, eₓ, e_{y}, and e_{z}. The circuit has three finite field symbol inputs representing the intermediate variables W 408, A 409, and S 410. With preferred weights and associated weights, the circuit has three subfield inputs representing successive values of the intermediate scalars Sc 608, Ac 609, and Wc 610. The output of three weighting multipliers 200 is summed in a three-input finite field adder unit 505. In three successive output cycles, the error values eₓ, e_{y}, and e_{z} are successively provided at the output of 505.

### B.4. Single Error Correction

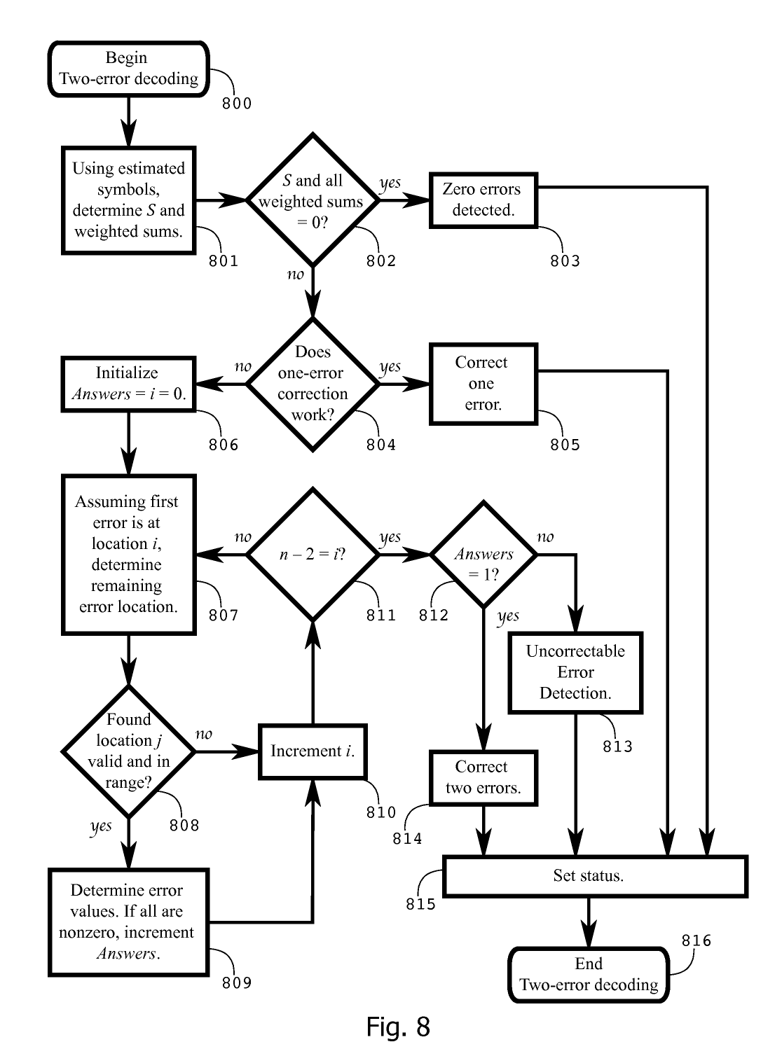

FIG. 8 is a flowchart of steps of an example method to decode one or more erroneous symbols with unmarked error locations, the steps of the method beginning with step 800. When there is only one error, Section A provides a decoding method for a single error. In this section, there is an additional redundant symbol that can be used to augment the reliability of the single error decoding method.

Let an estimated symbol be denoted hᵢ. The error decoder first determines the intermediate variables in step 801 representing a finite field sum S and two weighted sums, W and A, as in the previous section.

If there is a single error in the estimated sequence, hᵢ=cᵢ+eᵢ for some 0≦i<n and hⱼ=cⱼ for i≈j. It follows that S=eᵢ, W=wᵢeᵢ, and A=aᵢeᵢ. Following the decoding algorithm of the previous section, if S and W are nonzero, the location weight

wᵢ=W/S

is pre-assigned to the location i. Here, the prospective solution is checked further against the remaining redundancy. The check passes if the associated weight pre-assigned to the location i satisfies

A+aᵢeᵢ=A+aᵢS=0,

the sum determined using finite field addition. If the associated weight is the preferred aᵢ=wᵢ⁻¹, this further check can be provided by an alternative equivalent check,

wᵢA+S=0.

In the attempt at single error decoding, the intermediate values are checked in various steps for consistency with a single error solution. Step 802 checks if S=W=A=0; if so, no errors are assumed in step 803, the decoder sets appropriate status flags in 815 and quits in step 816. Otherwise, single error decoding is attempted in step 804. If both W and S are nonzero, a preliminary single error solution determines the weight pre-assigned to the error location, and checks that it is a member of the correct subfield and within range for a codeword, as discussed above in Section A. If so, a test of the further check provided here is performed. If all checks pass, the single error solution is provided in step 805 and the decoder sets appropriate status flags in 815 and quits in step 816.

If at least one of S, W, or A is nonzero, and all checks of a single error solution do not pass, correction of two symbol errors in the codeword (i.e., double error correction) is attempted, the flowchart proceeding from step 804 to 806. In initialization step 806, a viable solution counter with output Answers and an index i are both reset to zero.

### B.5. Double Error Correction

If there are two symbol errors in the estimated sequence, the decoder has two symbol errors in unknown locations i and j, such that

hᵢ=cᵢ+eᵢ for some 0≦i<n,

hⱼ=cⱼ+eⱼ for some 0≦j<n with i≈j and

h_{g}=c_{g} otherwise.

It follows that the intermediate variables, as determined above, satisfy

S=eᵢ+eⱼ,

W=wᵢeᵢ+wⱼeⱼ, and

A=aᵢeᵢ+aⱼeⱼ.

Suppose that a first error occurred at location i, with pre-assigned weight wᵢ. Note that

wᵢS+W=(wᵢ+wⱼ)eⱼ=wⱼeⱼ(1+wⱼ⁻¹wᵢ),

Case B.4.i: In the case that associated weights are pre-assigned such that aⱼ=wⱼ⁻¹,

wᵢA+S=eⱼ(1+wⱼ⁻¹wᵢ).

If eⱼ≈0, a solution for the pre-assigned weight of the second error is provided by

wⱼ=(wᵢS+W)/(wᵢA+S).

Case B.4.ii: In this case, associated weights are pre-assigned with aⱼ=wⱼ², so

wᵢW+A=wⱼeⱼ(wᵢ+wⱼ).

If eⱼ≈0, a solution for the pre-assigned weight of the second error is provided by

wⱼ=(wᵢW+A)/(wᵢS+W).

If the assumption of two errors is correct, a pre-assigned weight associated with the location of the second error is determined in either case in step 807. If a set of preferred weights is contained within a subfield, the pre-assigned weight can be determined and checked through a simplified subfield division and range checking as described in conjunction with FIG. 3 above. The viability and range checking of the determined location is performed in step 808. For each first error location i, the location of the second error, j, is required to be in the range i<j≦n−1. The assumption of two nonzero error values is checked in step 809.

The method described above solves for a second error location given a location of the first error. To ensure that the decoder correctly identifies the location of the first error, the decoder tries each possible first error location i, where 0≦i<n−1, cycling in the flowchart repeatedly through steps 807 to 811, each cycle incrementing i at step 810, until all locations have been tried. When all possible first locations have been tried at step 811, the total number of viable solutions for a correctable error pattern is checked in step 812. If there is only one viable solution, the decoding of two error values continues. The solution of the matrix equation

$$[ \begin{matrix}1 & 1 \\ {w}_{i} & {w}_{j}\end{matrix} ] [ \begin{matrix}{e}_{i} \\ {e}_{j}\end{matrix} ] = [ \begin{matrix}S \\ W\end{matrix} ]$$

provides the two error values determined in step 809,

eᵢ=(wⱼS+W)/(wᵢ+wⱼ), and

eⱼ=(wᵢS+W)/(wᵢ+wⱼ)=S+eᵢ.

If the total number of viable solutions observed at the output of the viable solution counter is other than one, the decoder flags the codeword as uncorrectable in step 813. Otherwise, the two-error solution is provided in step 814. In either case, the decoder sets appropriate status flags in 815 and quits in step 816.

FIG. 9 is a schematic of an example circuit to determine two error values. In a preferred implementation, weights are members of a subfield. The circuit has four inputs, the intermediate variables S 410 and W 408, and the two location weights, wᵢ 900 and wᵢ 901, supplied by an external controller. A first weighting multiplier 200 provides the product wᵢS to a first finite field adder unit 102, with output wᵢS+W. A subfield adder unit 612 provides the sum wᵢ+wⱼ. The output of 612 is inverted in subfield inverter 615. A second weighting multiplier 200 provides a first output eᵢ 903. If desired, a second finite field adder unit 102 provides a second parallel output eᵢ 902. Alternatively, the second adder unit 102 can be omitted, and the remaining circuitry can be used to produce a second sequential output of the circuit, eᵢ, when the inputs 900 and 901 are swapped: wⱼ on input 900 and wᵢ on input 901.

### B.6. Probabilistic Decoding

The double error decoding method of the previous section attempts to solve a system of three equations for four unknowns (two error locations and two error values). As such, the system of equations is undetermined and can have more than one solution. If there is more than one viable solution, the codeword is considered uncorrectable. Here, the conditional probability that a codeword with exactly two symbol errors is uncorrectable is approximated.

Assume that the actual locations of the two symbol errors are x and y. If the assumption of any other location i within a codeword results in a solution with a paired location j within the codeword, another potential solution has been found. There are exactly

$$( \begin{matrix}n - 2 \\ 2\end{matrix} ) = ( n - 2 ) ( n - 3 ) / 2$$

remaining pairs of locations (i, j) in a codeword with n symbols and one pair of actual error locations. Assuming that only one of (Q−1) equally probable quotients results in the paired value for j, the probability of a second viable solution, ignoring the nonzero error value check, is

Pr[uncorrectable given two errors]<n²/2(Q−1).

To provide an acceptably low uncorrectable rate, a large finite field with n²<<Q is utilized for coding purposes. For example, decoding a (255, 252) code in codewords with two errors results in an uncorrectable rate below 1E-5 with 32-bit code symbols, or below 1E-14 with 64-bit symbols.

It should be noted that the decoding method specified here is probabilistic, unlike the deterministic prior art Reed Solomon decoding methods cited in the introduction above. When two errors occur, a typical BMA error decoder for double error correction operates on codewords with four redundant symbols, and solves a deterministic system of four equations in four unknowns. Prior art MBMA decoders for double error correction with only three redundant symbols require a correct erasure indicator, and solve a deterministic system of three equations in three unknowns, assuming that only one such solution exists.

In contrast, the decoding algorithm for two symbol errors specified here is probabilistic. When two errors occur, the specified method solves an underdetermined system of three equations in four unknowns, assuming there may be more than one solution. The method relies on the use of a relatively large symbol field to make the probability of an ambiguous solution small.

What is claimed is:

1. An apparatus to decode one or more finite field symbol errors in a coded sequence of N finite field symbols, the apparatus comprising a unit to determine a plurality of weighted sums from the sequence, a unit to determine and check unknown error locations, and a unit to determine and check unknown error values at determined error locations, said apparatus operative to
(a) determine one or more sets of prospective error locations as a function of the weighted sums,
(b) determine prospective symbol error values at the prospective error locations in each set of prospective error locations,
(c) check each set of determined prospective error locations and associated symbol error values for a valid decoding solution, and
(d) correct a valid and unambiguous decoding solution by adding the symbol error values at the prospective error locations of a set of prospective error locations in a valid decoding solution.

2. The apparatus of claim 1, wherein the unit to determine a plurality of weighted sums from the sequence provides a finite field accumulation of products, each of said products comprising a finite field symbol multiplied by a weight from a smaller subfield of the finite field.

3. The apparatus of claim 1, wherein the unit to determine and check unknown error locations utilizes a simplified determination unit assuming valid weights are from a smaller subfield of the symbol field.

4. The apparatus of claim 1, wherein the unit to determine error locations determines one or more unknown error locations as a function of an assumed error location.

5. The apparatus of claim 1, wherein the check of a set of prospective error locations includes
(a) a check if the one or more prospective error locations are associated with weights from a smaller subfield of the symbol field,
(b) a check if the one or more prospective error locations are legitimate locations within the N locations in the sequence, and
(c) a check if the one or more prospective error values are nonzero.

6. The apparatus of claim 1, wherein the check for a valid and unambiguous decoding solution includes a check that there is only one valid decoding solution.

7. The apparatus of claim 1, wherein the number of elements in the finite field is large compared to the number of symbols, N, in the coded sequence.

8. The apparatus of claim 1, wherein the number of elements in the finite field is large compared to the square of the number of symbols in the coded sequence, N².

9. The apparatus of claim 1, wherein the set of weights used in determining at least one of the determined weighted sums spans a linear range.

10. A method to decode one or more finite field symbol errors in a coded sequence of N finite field symbols, the method comprising a plurality of steps,
(a) a step to determine one or more sets of prospective error locations as a function of a plurality of weighted sums, each of said weighted sums determined from the coded sequence,
(b) a step to determine prospective symbol error values at the prospective error locations in each set of prospective error locations,
(c) a step to check each set of determined prospective error locations and associated symbol error values for a valid decoding solution, and
(d) a step to correct a valid and unambiguous decoding solution by adding the symbol error values at the error locations of a set of prospective error locations in a valid decoding solution.

11. The method of claim 10, wherein the step to determine a plurality of weighted sums from the sequence provides a finite field accumulation of products, each of said products comprising a finite field symbol multiplied by a weight from a smaller subfield of the finite field.

12. The method of claim 10, wherein the step to determine and check unknown error locations utilizes a simplified determination unit assuming valid weights are from a smaller subfield of the symbol field.

13. The method of claim 10, wherein the step to determine error locations determines one or more unknown error locations as a function of an assumed error location.

14. The method of claim 10, wherein the check of a set of prospective error locations includes
(a) a check if the one or more prospective error locations are associated with weights from a smaller subfield of the symbol field,
(b) a check if the one or more prospective error locations are legitimate locations within the N locations in the sequence, and
(c) a check if the one or more prospective error values are nonzero.

15. The method of claim 10, wherein the check for a valid and unambiguous decoding solution includes a check that there is only one valid decoding solution.

16. The method of claim 10, wherein the number of elements in the finite field is large compared to the number of symbols, N, in the coded sequence.

17. The method of claim 10, wherein the number of elements in the finite field is large compared to the square of the number of symbols in the coded sequence, N².

18. The method of claim 10, wherein the set of weights used in determining at least one of the determined weighted sums spans a linear range.
